(19) United States
(12) Patent Application Publication
(10) Pub. No.: US 2010/0127398 A1
(43) Pub. Date: May 27, 2010

(54) Wiring structure of a semiconductor device

(75) Inventors: Young-Hoo Kim, Seongnam-si (KR); Chang-Ki Hong, Seongnam-si (KR); Jae-Dong Lee, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/592,042

(22) Filed: Nov. 18, 2009

(30) Foreign Application Priority Data
Nov. 21, 2008 (KR) 10-2008-0116122

(51) Int. Cl. H01L 23/498

(52) U.S. Cl. 257/773; 257/E23.07

(57) ABSTRACT

In a wiring structure of a semiconductor device and a method of manufacturing the same, a wiring structure includes a contact pad, a contact plug, a spacer and an insulation interlayer pattern. The contact pad is electrically connected to a contact region of a substrate. The contact plug is provided on the contact pad and is electrically connected to the contact pad. The spacer faces an upper side surface of the contact pad and sidewalls of the contact plug. The insulation interlayer pattern has an opening, the contact plug and the spacer being provided in the opening. The spacer of the wiring structure may prevent the contact pad from being damaged by a cleaning solution while forming a contact plug to be connected to a capacitor.

### CROSS-REFERENCE TO RELATED PATENT APPLICATION

This application claims priority under 35 U.S.C. §119 to Korean Patent Application No. 10-2008-0116122, filed on Nov. 21, 2008 in the Korean Intellectual Property Office (KIPO), the contents of which are herein incorporated by reference in their entirety.

### BACKGROUND

1. Field

Exemplary embodiments relate to a wiring structure of a semiconductor device and a method of forming the same. More particularly, exemplary embodiments relate to a wiring structure of a semiconductor device capable of preventing an electrical short between contact plugs and a method of forming the same.

2. Description of the Related Art

As a memory cell of a DRAM device is more highly integrated, a lateral area of each cell is greatly reduced. Accordingly, it may be important to form a capacitor having a high capacitance in the reduced area.

In order to increase an effective area of an electrode included in the capacitor, various capacitor structures have been researched. Examples of the capacitor structures include a planar type capacitor, a stack type or trench type capacitor, a cylinder type capacitor, etc. Cylinder type capacitors may be required to be formed in a relatively small area without making contact with one another. However, because the capacitor is electrically connected to one source/drain region of an access transistor, a region in which the capacitor is to be formed may be limited according to the position of the underlying source/drain. Accordingly, electrical short problems between adjacent capacitors may occur frequently with a reduced margin therebetween.

Recently, new processes have been developed to ensure that adjacent capacitors may be arranged to be spaced apart by a sufficient distance without regard to the positions of the underlying source/drains. For example, a contact plug to be connected to the capacitor may be formed to have an upper surface wider than a lower surface of the contact plug. A landing pad may be further formed on the upper surface of the contact plug, to thereby increase a contact margin between the capacitor and the contact plug. However, when the contact plug has an upper surface wider than the lower surface, the distance between the adjacent contact plugs may be greatly decreased so that a bridge failure between the contact plugs occurs frequently. Further, when the landing pad is further formed on the upper surface of the contact plug, additional deposition and photolithography processes may be performed. Further, a failure due to misalignment of the landing pad may occur.

Accordingly, processes of forming a contact plug having an upper surface of a sufficient area and capable of preventing a bridge failure between a contact plug and a pad contacting a bit line have been developed. For example, in a DRAM device of sub-60 nm design rule, a contact plug to be connected to a lower electrode may be formed in an opening that exposes a first contact pad in an intersecting region of a word line structure and a bit line structure and has a spacer formed therein. Accordingly, the contact plug may be formed to be adjacent to the bit line structure and a second pad to be connected to the bit line structure. Since the opening is formed by a self-alignment process using the bit line structure as an etching mask, the opening may expose the bit line or the second pad.

### SUMMARY

Exemplary embodiments provide a wiring structure of a semiconductor device having a spacer facing a contact pad and a contact plug.

Exemplary embodiments provide a method of manufacturing the wiring structure of a semiconductor device including forming a spacer facing a contact pad and a contact plug to thereby prevent damage of the contact pad by a cleaning solution.

According to one aspect, the inventive concept is directed to a wiring structure which includes a contact pad, a contact plug, a spacer and an insulation interlayer pattern. The contact pad is electrically connected to a contact region of a substrate. The contact plug is provided on the contact pad and is electrically connected to the contact pad. The spacer faces an upper side surface of the contact pad and sidewalls of the contact plug. The insulation interlayer pattern has an opening, the contact plug and the spacer being provided in the opening. The spacer of the wiring structure may prevent the contact pad from being damaged by a cleaning solution while forming a contact plug to be connected to a capacitor.

In an exemplary embodiment, a lower portion of the opening may have a width greater than a width of an upper surface of the contact pad. The contact pad may be adjacent to a contact pad for a capacitor, the contact pad for a capacitor being electrically connected to the contact region of the substrate.

In an exemplary embodiment, the spacer may surround an upper sidewall of the contact pad, and the spacer may include silicon nitride or silicon oxinitride.

In an exemplary embodiment, the wiring structure may further include a bit line that is electrically connected to the contact plug.

According to another aspect, the inventive concept is directed to a method of forming a wiring structure of a semiconductor device. According to the method, a substrate is prepared and an insulation interlayer is formed to cover a contact pad that is electrically connected to a contact region of the substrate. The insulation interlayer is patterned to form an insulation interlayer pattern having an opening that exposes an upper surface and an upper side surface of the contact pad. A spacer is formed on sidewalls of the opening of the insulation interlayer pattern, the spacer facing the upper side surface of the contact pad. A contact plug is formed in the opening having the spacer formed therein, the contact plug being electrically connected to the contact pad. The wiring structure may be prevented from being damaged by a cleaning solution while forming a following contact plug to be connected to a capacitor.

In an exemplary embodiment, a lower portion of the opening may be formed to have a width of about 10 to 30 nm greater than a width of the upper surface of the contact pad.

In an exemplary embodiment, forming the spacer may include forming a spacer layer using silicon nitride or silicon oxinitride and etching the spacer layer until the surface of the contact pad is exposed, to form the spacer.

According to another aspect, the inventive concept is directed to a method of forming a wiring structure of a semiconductor device. According to the method, a first insulation interlayer pattern is formed to have first openings that expose contact regions of a substrate. A first contact pad and a second contact pad are formed in the first openings of the first insulation interlayer pattern. A second insulation interlayer is formed to cover the first and second contact pads. The second insulation interlayer is patterned to form a second insulation interlayer pattern having a preliminary opening that exposes an upper surface of the first contact pad and a portion of a surface of the first insulation interlayer pattern. An upper portion of the first insulation interlayer pattern exposed through the preliminary opening is etched to form an opening that exposes the upper surface and an upper side surface of the first contact pad. A spacer is formed on sidewalls of the opening of the first and second insulation interlayer patterns, the spacer facing the upper side surface of the first contact pad. A bit line structure having a contact plug is formed in the opening having the spacer formed therein.

As described above, a wiring structure according to exemplary embodiments includes a spacer that surrounds not only an outer side surface of a contact plug formed on a contact pad but also an upper outer side surface of the contact pad. That is, the spacer may be formed to surround portions of the contact pad and the contact plug facing each other. Accordingly, metal silicide formed between contact surfaces of the contact pad and the contact plug may be prevented from being damaged by permeation of a cleaning solution while forming an adjacent contact plug. Thus, the contact pad may be prevented from being damaged during a subsequent process of forming a contact plug to be connected to a capacitor, to thereby prevent an electrical short between adjacent contact plugs.

### BRIEF DESCRIPTION OF THE DRAWINGS

The foregoing and other features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a cross-sectional view illustrating a wiring structure of a semiconductor device in accordance with an exemplary embodiment.

FIGS. 2 to 5 are cross-sectional views illustrating a method of forming the wiring structure in FIG. 1 in accordance with an exemplary embodiment.

FIGS. 6 to 18 are cross-sectional views illustrating a method of manufacturing a DRAM device including a wiring structure in accordance with an exemplary embodiment.

### DETAILED DESCRIPTION OF THE EMBODIMENTS

Various exemplary embodiments will be described more fully hereinafter with reference to the accompanying drawings, in which some exemplary embodiments are shown. The present inventive concept may, however, be embodied in many different forms and should not be construed as limited to the exemplary embodiments set forth herein. Rather, these exemplary embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be described in detail with reference to the accompanying drawings.

### Wiring Structure and Method of Forming the Wiring Structure

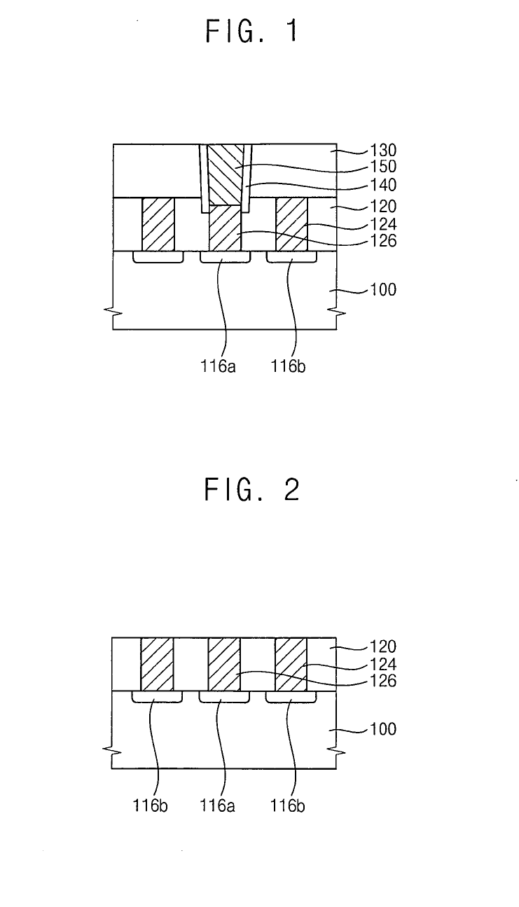

FIG. 1 is a cross-sectional view illustrating a wiring structure of a semiconductor device in accordance with an exemplary embodiment.

Referring to FIG. 1, a semiconductor structure according to an exemplary embodiment includes a substrate 100, contact pads 124 and 126 electrically connected to contact regions 116b and 116a, respectively, an insulation layer pattern 120 for insulating the contact pads, an insulation interlayer pattern 130 having an opening that exposes a portion of the contact pad, a contact plug 150 electrically connected to the contact pad, and a spacer 140 facing an upper side surface of the contact pad 126 and sidewalls of the contact plug 150.

The substrate 100 may include a silicon substrate, a silicon-on-insulator substrate, a germanium substrate, a silicon-germanium substrate, etc. An isolation layer may be provided in the substrate 100 by a shallow trench isolation (STI) process. A gate structure (not illustrated) and a contact region may be provided in the substrate 100. The gate structure may be a word line having a stack structure of a gate insulation layer and a gate electrode. The contact regions may include a first contact region 116a and a second contact region 116b.

The contact pads may include a first contact pad 124 and a second contact pad 126. The first contact pad 124 may make contact with the first contact region 116b. The first contact pad 124 may be electrically connected to a contact plug for a capacitor. The second contact pad 126 may make contact with the second contact region 116a. The second contact pad 126 may be electrically connected to a contact plug for a bit line. For example, the second contact pad 126 may have an upper surface lower than that of the first contact pad 124. The contact pads may include polysilicon doped with impurities. The first and second contact pads 124 and 126 may be arranged repeatedly. The first and second contact pads 124 and 126 may be electrically insulated by the insulation layer pattern 120.

The insulation interlayer pattern 130 may be formed by patterning an insulation interlayer covering the contact pads 124 and 126. The insulation interlayer pattern 130 may have an opening (not illustrated) that exposes the upper surface of the second contact pad 126. The opening may penetrate the insulation interlayer and may have a structure to be connected to a recess (not illustrated) formed due to over-etching of the insulation interlayer. The recess may expose the upper surface and the upper side surface of the second contact pad 126. That is, a lower portion of the opening has a width greater than a width of the upper surface of the second contact pad 126.

The spacer 140 may be provided on sidewalls of the opening of the insulation interlayer pattern 130. The spacer 140 may face the upper side surface of the second contact pattern 126. That is, the spacer 140 may be formed in the opening and surround the upper sidewall of the second contact pad 126. The spacer 140 may be formed to the upper sidewall of the second contact pad 126. Accordingly, metal silicide formed between contact surfaces of the second contact pad 126 and the contact plug for a bit line may be prevented from being damaged by a cleaning solution. Thus, the contact plug for a capacitor may be prevented from being electrically connected to the second contact pad 126 while forming the contact plug for a capacitor to be electrically connected to the first contact pad 124.

The contact plug 150 may be formed in the opening having the spacer 140 formed therein to be electrically connected to the second contact pad 126 of the contact pads. The contact plug 150 may be a lower metal pattern to be electrically connected to a bit line (not illustrated) or a lower metal wiring included in a bit line. Although it is not illustrated in the figure, in this embodiment, a conductive wiring structure may further include a bit line to be electrically connected to the contact plug 150.

FIGS. 2 to 5 are cross-sectional views illustrating a method of forming the wiring structure in FIG. 1 in accordance with an exemplary embodiment.

Referring to FIG. 2, contact pads 124 and 126 are formed on a substrate 100.

In an exemplary embodiment, an insulation layer 120 may formed to cover the substrate having contact regions 116a and 116b formed therein. The insulation layer may include a silicon oxide. Examples of the silicon oxide may be BPSG, PSG, USG, TEOS, HDP oxide, etc. The insulation layer may have an upper surface that is planarized by a chemical mechanical polishing process.

A photoresist pattern (not illustrated) may be formed on the insulation layer. A portion of the insulation layer that is exposed through the photoresist pattern may be anisotropically etched to form contact holes (not illustrated) that expose the contact regions 116a and 116b. The insulation layer may be partially removed to form an insulation layer pattern 120 having the contact holes. Some of the contact holes may expose a first contact region 116b that serves as a capacitor contact region. Others of the contact holes may expose a second contact region 116a that serves as a bit line contact region.

First and second contact pads 124 and 126 may be formed in the contact holes of the insulation layer pattern 120, respectively. In particular, a polysilicon layer (not illustrated) may be formed to fill and cover the insulation layer pattern 120. For example, the polysilicon layer may be formed using polysilicon doped with impurities by a chemical vapor deposition process.

The polysilicon layer on the upper surface of the insulation layer pattern 120 may be selectively removed to form first and second polysilicon patterns in the contact holes. The first polysilicon pattern in the contact hole may be the first contact pad 124 that is electrically connected to the first contact region 116b. The second polysilicon pattern in the contact hole may be the second contact pad 126 that is electrically connected to the second contact region 116a. Upper surfaces of the first and second contact pads 124 and 126 may have the same heights as the upper surface of the insulation layer pattern.

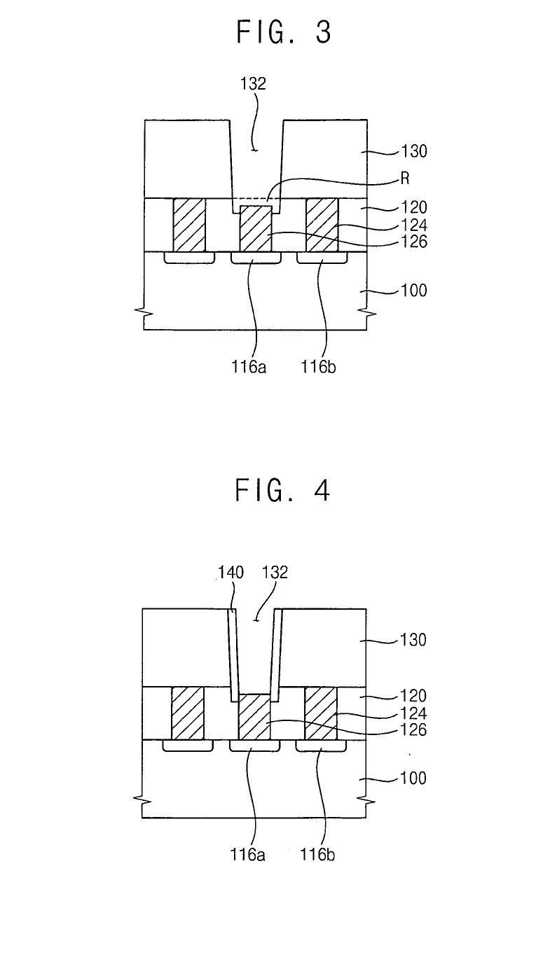

Referring to FIG. 3, an insulation interlayer pattern 130 is formed on the substrate 100. The insulation interlayer pattern 130 may have an opening 132 that exposes the upper surface and an upper portion of a side surface of the contact pad.

In an exemplary embodiment, an insulation interlayer (not illustrated) may be formed on the substrate 100 having the first contact pad 124 and the second contact pad 126 formed thereon. The insulation interlayer may insulate the first contact pad 124 from a bit line to be formed by a subsequent process. The insulation interlayer may include a BPSG oxide layer, a PSG oxide layer, a SOG oxide layer, a HDP oxide layer, etc.

A second photoresist pattern (not illustrated) is formed on the insulation interlayer. A lower portion of the opening 132 to be formed using the second photoresist pattern may have a width greater than a width of the upper surface of the second contact pad 126. The insulation interlayer exposed through the second photoresist pattern may be over-etched until an upper sidewall of the second contact pad is exposed, to form the insulation interlayer pattern 130 having the opening 132 that exposes the upper surface and the upper sidewall of the second contact pad 126. For example, the width of the lower portion of the opening 132 may be about 10 to 30 nm greater than the width of the upper surface of the contact pad.

Due to the over-etching of the insulation interlayer to form the opening 132, the second contact pad 126 may have an upper surface lower than that of the first contact pad and a recess R may be formed in the insulation layer pattern to be connected to the opening. That is, the opening 132 may be connected to the recess in the insulation layer pattern to expose an upper portion of the second contact pad.

Referring to FIG. 4, a spacer 140 is formed on sidewalls of the insulation interlayer pattern exposed through the opening.

In an exemplary embodiment, the second photoresist pattern may be removed from the insulation interlayer pattern by an ashing and/or strip processes. A spacer layer (not illustrated) is formed on the sidewalls of the insulation interlayer pattern 130 and on the second contact pad 126 exposed through the opening 132. For example, the spacer layer may be formed using silicon nitride or silicon oxinitride by a chemical vapor deposition process. The spacer layer may be anisotropically etched until the surface of the second contact pad 126 is exposed, to form the spacer 140 on the sidewalls of the insulation layer pattern 120 and the insulation interlayer pattern 130 exposed through the opening 132. The spacer 140 may surround and face the upper sidewall of the second contact pad 126 that is exposed through the opening 132. For example, when the second contact pad 126 has a width of about 40 to 50 nm, the spacer may be formed to have a width of about 8 to 14 nm.

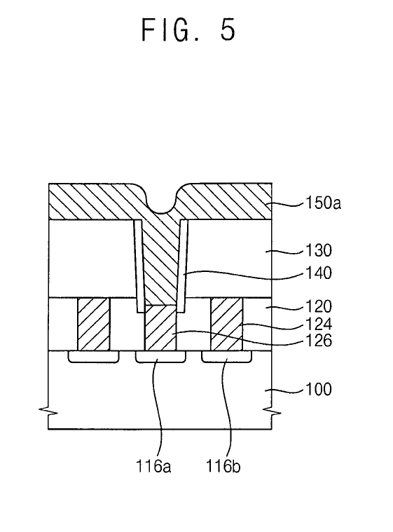

Referring to FIG. 5, a metal layer 150a is formed in the opening having the spacer 140 formed therein. In an exemplary embodiment, the metal layer 150a may be formed to fill the opening 132 having the spacer 140 formed therein and cover the insulation interlayer pattern 130. For example, titanium or tungsten metal may be deposited to form the metal layer 150a. When the metal layer 150a is formed, a metal silicide layer (not illustrated) may be formed in the surface of the second contact pad 126 including polysilicon.

The upper portion of the metal layer may be planarized by a chemical mechanical polishing process, to form a contact plug 150 in the opening 132 as illustrated in FIG. 1. The contact plug 150 may be electrically connected to the second contact pad 126. In this embodiment, the chemical mechanical polishing process may be performed until an upper portion of the insulation interlayer pattern 130 is partially removed.

As described above, the wiring structure includes the spacer that surrounds and faces the sidewalls of the second contact pad 126 and the contact plug 150. Accordingly, the second contact pad 126 may be prevented from being damaged by a cleaning solution during a formation of a contact plug for a capacitor.

Hereinafter, a method of manufacturing a DRAM device using a method of forming a wiring structure in accordance with an exemplary embodiment will be described.

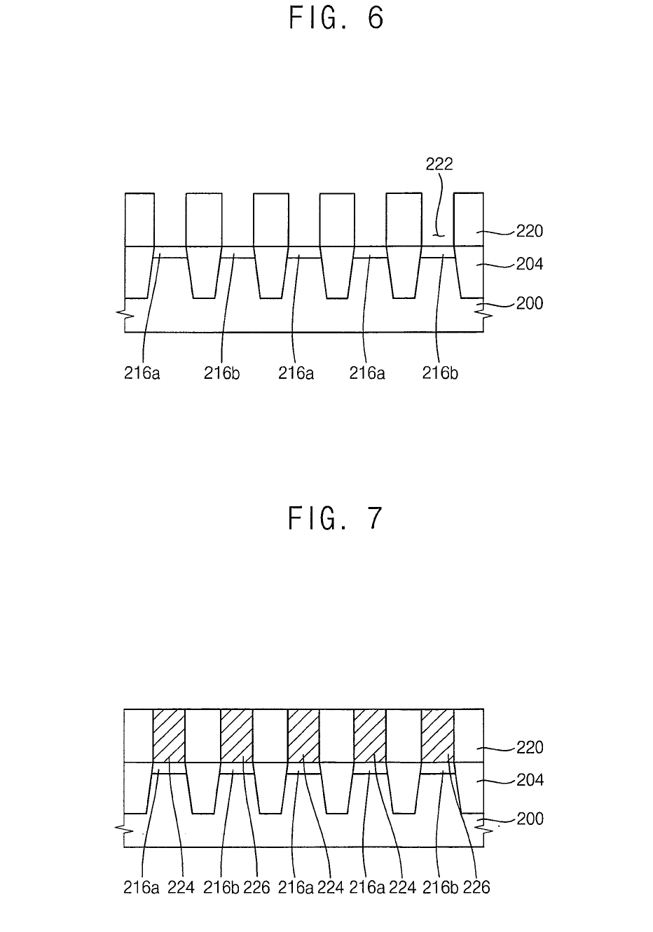

FIGS. 6 to 18 are cross-sectional views illustrating a method of manufacturing a DRAM device including a wiring structure in accordance with an exemplary embodiment.

Referring to FIG. 6, a first insulation interlayer pattern 220 is formed on a substrate 200. The first insulation interlayer pattern 220 has first openings formed therein that expose contact regions 216a and 216b.

In an exemplary embodiment, an isolation layer 204 may be formed in the substrate 200 to define an active region. Then, a transistor (not illustrated) including a gate structure (not illustrated) and the contact regions 216a and 216b may be formed in the active region of the substrate.

The gate structure may include a word line having a stacked structure of a gate insulation layer and a gate electrode and a gate spacer. Impurities may be implanted using the gate structures as an ion implanting mask under surfaces of the substrate exposed between the gate structures. Then, a thermal treatment process may be performed on the substrate to form the contact regions 216a and 216b that serve as source/drain regions. The contact regions may include a first contact region 216a and a second contact region 216b. The first contact region 216a may make contact with a first contact pad that is electrically connected to a capacitor. The second contact region 216b may make contact with a second contact pad that is electrically connected to a bit line.

A first insulation interlayer may be formed to cover the gate structure. The first insulation interlayer may be formed using silicon oxide by a chemical vapor deposition process. An etch mask may be formed on the first insulation interlayer, and then, the first insulation interlayer may be etched using the etch mask, to form the first insulation interlayer pattern 220. The first insulation interlayer pattern 220 may have first openings 222 that respectively expose the first contact region 216a and the second contact region 216b. The first openings 222 may be formed by a self-align contact forming process where the first openings 222 are self-aligned by the gate spacers.

Referring to FIG. 7, contact pads 224 and 226 are formed in the first openings of the first insulation interlayer pattern 220.

In an exemplary embodiment, a polysilicon layer (not illustrated) may be formed to fill the first opening and cover the first insulation interlayer pattern 220. The polysilicon layer may be selectively removed until an upper surface of the first insulation layer pattern 220 is exposed, to form the contact pads 224 and 226 in the first openings.

The contact pads may include a first contact pad 224 and a second contact pad 226. The first contact pad 224 may be a polysilicon pattern in the first opening to be electrically connected to the first contact region 216a. The second contact pad 226 may be a polysilicon pattern in the opening to be electrically connected to the second contact region 216b.

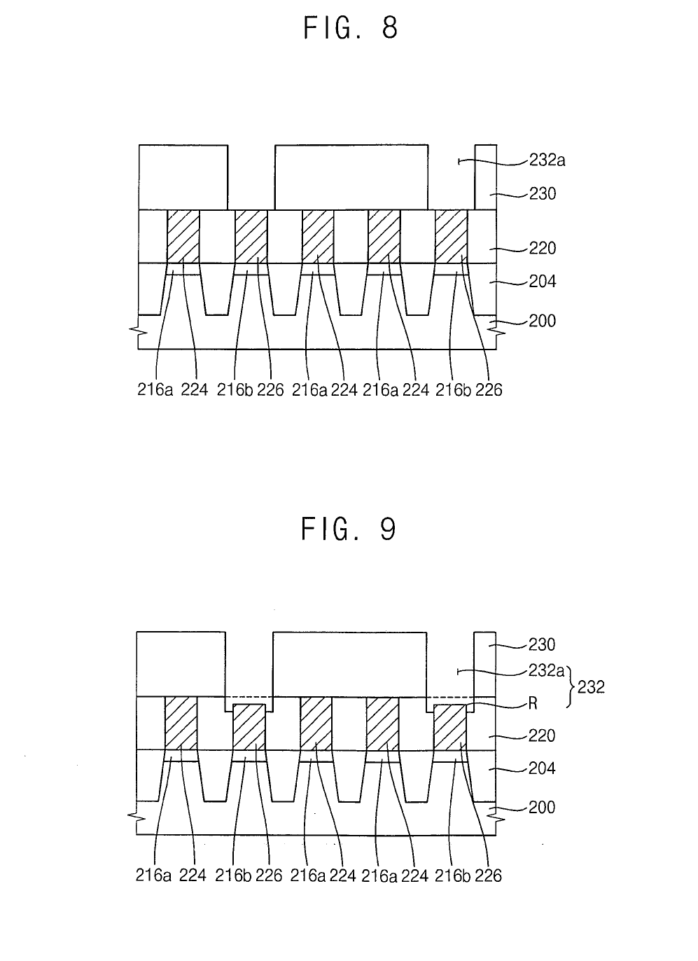

Referring to FIG. 8, a second insulation interlayer pattern 230 is formed on the first insulation interlayer pattern 220. The second insulation interlayer pattern 230 has a preliminary second opening 232a that partially exposes upper surfaces of the second contact pad 226 and the first insulation interlayer pattern 220.

In an exemplary embodiment, a second insulation interlayer (not illustrated) may be formed on the first insulation interlayer pattern 220 having the first contact pad 224 and the second contact pad 226. The second insulation interlayer may insulate a contact plug from an adjacent lower wiring of a bit line to be formed by a subsequent process. The second insulation interlayer may include a BPSG oxide layer, a PSG oxide layer, a SOG oxide layer, a HDP oxide layer, etc.

A second photoresist pattern (not illustrated) may be formed on the second insulation interlayer. A lower portion of the preliminary second opening 232a to be formed using the second photoresist pattern may have a width greater than a width of the upper surface of the second contact pad 226. The second insulation interlayer exposed through the second photoresist pattern may be patterned until the upper surface of the second contact pad 226 and the surface of the first insulation layer pattern are exposed, to form the second insulation interlayer pattern 230 having the preliminary second opening 232a that exposes the upper surface of the second contact pad 226 and the surface of the first insulation interlayer pattern. For example, the width of the lower portion of the preliminary second opening 232a may be about 10 to 30 nm greater than the width of the upper surface of the second contact pad 226.

Referring to FIG. 9, the upper portion of the first insulation interlayer pattern exposed through the preliminary second opening is etched to form a second opening 232 that exposes an upper sidewall of the second contact pad 226. In particular, when the upper portion of the first insulation interlayer pattern 220 exposed through the preliminary second opening 232a is etched, a recess R may be formed in the first insulation interlayer pattern 220 and connected to the preliminary second opening 232a. The recess R and the preliminary second opening 232a may form the second opening 232. In this embodiment, because the second contact pad 226 is exposed during an anisotropic etch process to form the recess R, the second contact pad 226 may have an upper surface lower than that of the first contact pad 224. The second opening 232 may expose the sidewalls of the second insulation interlayer pattern 230 and a portion of the sidewalls of the first insulation interlayer pattern 220.

Referring to FIG. 10, a spacer 240 is formed on the sidewalls of the second insulation interlayer pattern 230 exposed through the second opening 232.

In an exemplary embodiment, the second photoresist pattern may be removed from the second insulation interlayer pattern 230 by an ashing and/or strip processes. A spacer layer (not illustrated) is formed conformally on the sidewalls of the second insulation interlayer pattern 230 and on the second contact pad 226 exposed through the second opening 232. For example, the spacer layer may be formed using silicon nitride or silicon oxinitride by a chemical vapor deposition process. The spacer layer may be anisotropically etched until the surface of the second contact pad 226 is exposed, to form the spacer 240 on the sidewalls of the first insulation layer pattern 220 and the second insulation interlayer pattern 230 exposed through the second opening 232. The spacer 240 may surround and face the upper sidewall of the second contact pad 226 that is exposed through the second opening 232.

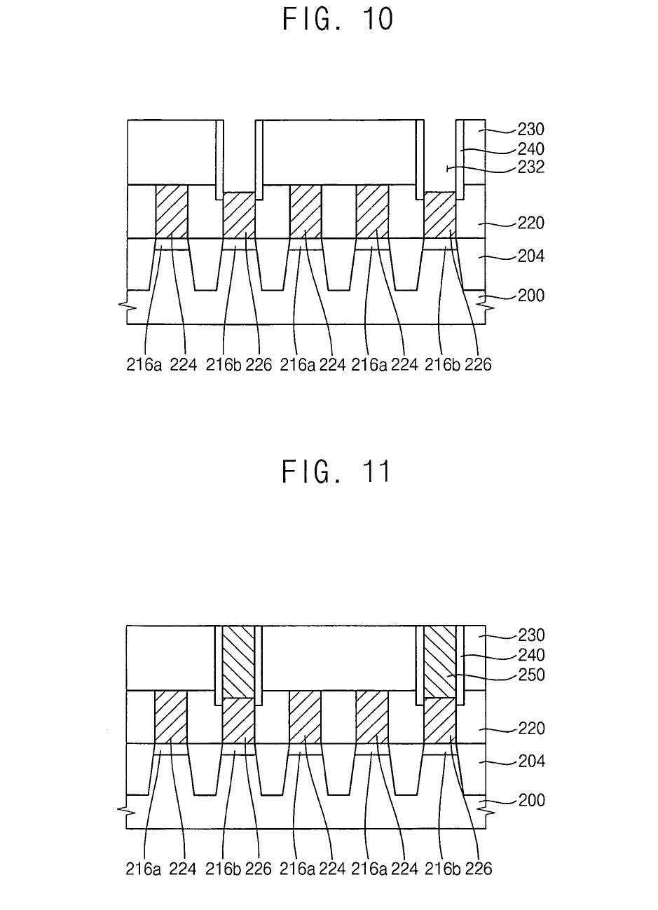

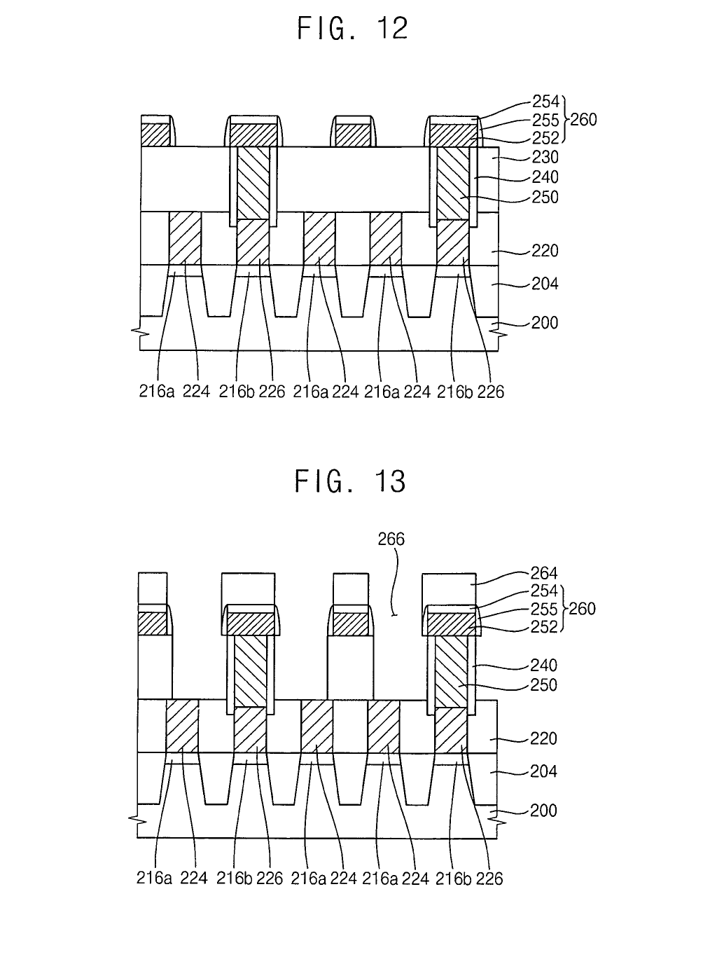

Referring to FIG. 11, a contact plug 250 for a bit line is formed in the second opening having the spacer formed therein. In an exemplary embodiment, a metal layer may be formed to fill the second opening 232 having the spacer 240 formed therein and cover the second insulation interlayer pattern 230. When the metal layer is formed, a metal silicide layer (not illustrated) may be formed in the surface of the second contact pad 226 including polysilicon. An upper portion of the metal layer may be planarized by a chemical mechanical polishing process, to form the contact plug 250 in the second opening 232 for a bit line that is electrically connected to the second contact pad 226. In this embodiment, the chemical mechanical polishing process may be performed until an upper portion of the second insulation interlayer pattern 230 is partially removed.

Referring to FIG. 12, a bit line structure 260 is formed to be electrically connected to the contact plug 250. In an exemplary embodiment, a bit line conductive layer (not illustrated) may be formed on the second insulation interlayer pattern 230 and the contact plug 250. After a mask pattern 254 is formed on the bit line conductive layer, the bit line conductive layer exposed through the mask pattern 234 may be patterned, to form a bit line that is electrically connected to the contact plug 250. A bit line spacer 255 may be formed on sidewalls of the bit line 252 and the mask pattern 254, to form the bit line structure 260 on the contact plug 250. The bit line structure 260 may include the bit line 252, the mask 254 and the bit line spacer 255.

Referring to FIG. 13, a third insulation interlayer 264 is formed to fill gaps between the bit line structures 260 and cover the bit line structures. The third insulation interlayer 264 may be formed using the same material as the first insulation interlayer and the second insulation interlayer. The third insulation interlayer 264 and the second insulation interlayer pattern 230 may be sequentially patterned to form a third opening 266 that exposes the first contact pad 224. For example, the third opening 266 may expose a portion of the spacer 240 surrounding the second contact pad 226.

Although it is not illustrated in the figure, a spacer for a bit line may be further formed on sidewalls of the third insulation interlayer and the bit line structure 260 exposed through the third opening.

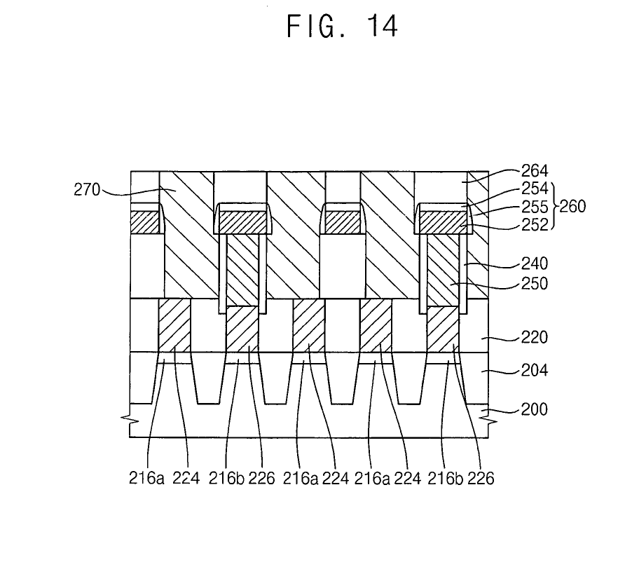

Referring to FIG. 14, a metal layer is formed to completely fill the third opening 266 and to cover the third insulation interlayer 264. The metal layer may be formed using tungsten, aluminum, copper, etc. The metal layer may be planarized until an upper surface of the third insulation interlayer 264 is exposed, to form a metal pattern. The metal pattern may be a contact plug 270 for a capacitor that is electrically connected to a lower electrode to be formed by a subsequent process.

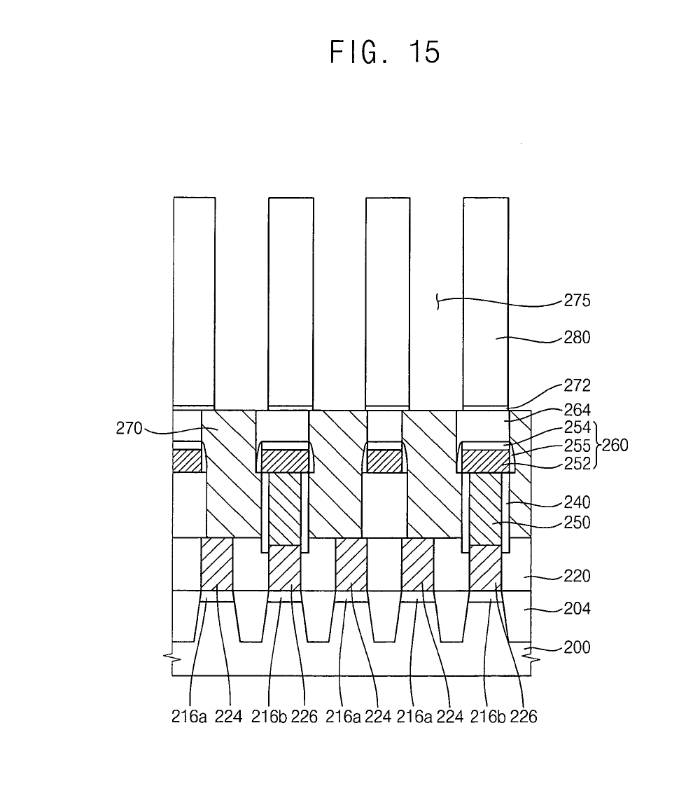

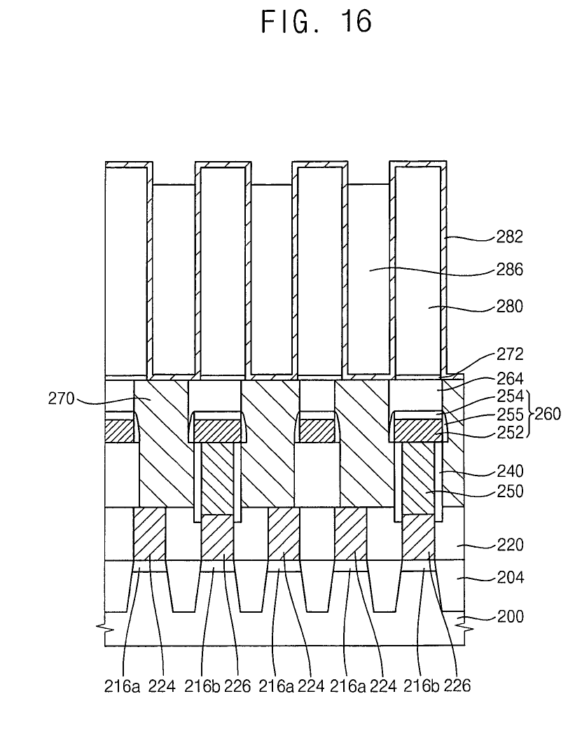

Referring to FIG. 15, an etch stop layer 272 is formed on the contact plug 270 for a capacitor and the third insulation interlayer 264. For example, the etch stop layer 272 may prevent the contact plug 270 for a capacitor from being damaged while a subsequent selective etch process is performed to form an opening 275 in a mold layer 280. The etch stop layer 272 may have a thickness about 10 to 200 Å. The etch stop layer may be formed using nitride or metal oxide having a relatively low etch rate with respect to the mold layer.

The mold layer 280 is formed on the etch stop layer 272. The mold layer 280 may be formed using silicon oxide. For example, the mold layer 280 may include TEOS, HDP-CVD oxide, PSG, USG, BPSG, SOC, etc. The mold layer 280 may have a multi layer structure of at least two different material layers. For example, at least two different material layers having different etch rates may be stacked to form the mold layer 280. In this case, shapes of sidewalls of the lower electrode of a capacitor to be formed by a subsequent process may be determined according to the combination of the material layers having different etch rates.

The thickness of the mold layer 280 may be determined according to a capacitance to be required for the capacitor. That is, since the height of the capacitor depends on the thickness of the mold layer 280, the thickness of the mold layer 280 may be determined in order to form a capacitor having a required capacitance.

The mold layer 280 and the etch stop layer 272 may be partially etched to form an opening 275 that exposes the contact plug 270. The etch stop layer 272 may be over-etched such that the etch stop layer does not remain on a bottom surface of the opening 275. Accordingly, although it is not illustrated, an upper surface of the contact plug 270 may be partially etched by the etch process.

Referring to FIG. 16, a lower electrode layer 282 is formed conformally on sidewalls and the bottom surface of the opening 275 and an upper surface of the mold layer 280. The lower electrode layer 282 may be formed using a material different from the underlying contact plug 270. The lower electrode layer 282 may include metal or a material having metal. The lower electrode layer 282 may be a single layer including titanium or titanium nitride. The lower electrode layer 282 may be a multi layer including titanium and titanium nitride. For example, the lower electrode layer 282 may have titanium/titanium nitride layer structure. When the lower electrode layer 282 is formed using metal or a material having metal instead of polysilicon material, a depletion layer may be prevented from being formed in an interface between a lower electrode and a dielectric layer to be formed by a subsequent process, to thereby increase a capacitance of the capacitor.

Since the lower electrode layer 282 is formed along the inner surface of the opening having a high aspect ratio, the lower electrode layer 282 may be formed by a deposition process having excellent step coverage characteristics. Further, the lower electrode layer 282 may be formed to have a small thickness not to completely fill the opening. For example, the lower electrode layer 282 may be formed by a chemical vapor deposition process, a cyclic chemical vapor deposition process, an atomic layer deposition process, etc.

A buffer layer pattern 286 may be formed in the opening having the lower electrode layer. The buffer layer pattern 286 may be formed using silicon oxide or polysilicon.

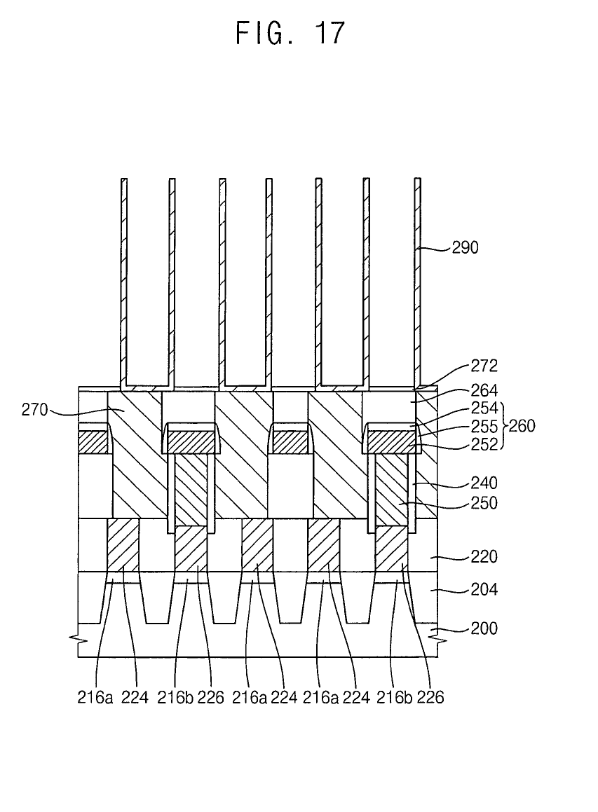

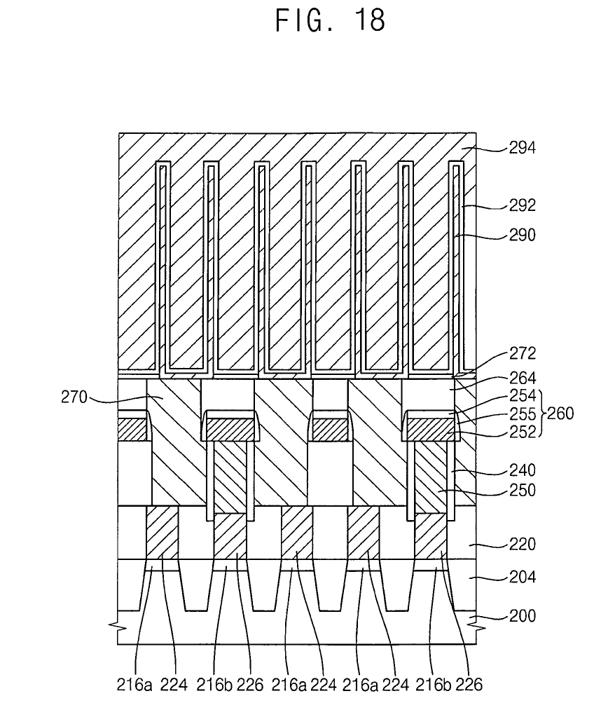

Referring to FIG. 17, the lower electrode layer 282 formed on the upper surface of the mold layer 280 is removed to form a lower electrode 290.

The lower electrode layer 282 may be etched using the buffer layer pattern 286 as an etching mask until the surface of the mold layer 280 is exposed, to form the lower electrode 290 having a cylinder shape. Thus, the buffer layer pattern 286 may remain within the cylinder shape of the lower electrode 290, and the mold layer 280 may surround the outer sidewalls of the lower electrode 290.

Then, the mold layer 280 and the buffer layer pattern 286 may be removed by a wet etch process using an etch solution. The mold layer 280 and the buffer layer pattern 286 including silicon oxide may be removed together by a wet etch process using a LAL solution including water, hydrofluoric acid and ammonium hydrogen fluoride. The LAL solution may further include an anti-corrosive agent and surfactant capable of preventing corrosion of the lower electrode and re-adsorption of oxide.

Referring to FIG. 18, a dielectric layer 292 is formed conformally on the lower electrode 290. The dielectric layer 292 may be formed using a metal oxide having a high dielectric constant. Examples of the metal oxide may be aluminum oxide, hafnium oxide, etc.

An upper electrode 294 is formed on the dielectric layer 292. The upper electrode 294 may be formed using metal or a material having metal. Alternatively, the upper electrode 294 may be a multi layer including metal or a material having metal and polysilicon deposited on the dielectric layer. The processes may be performed to complete a DRAM device including a capacitor.

As mentioned above, a wiring structure according to an exemplary embodiment includes a spacer that surrounds an outer side surface of a contact plug formed on a contact pad and an upper outer side surface of the contact pad at the same time. That is, the spacer may be formed to surround portions of the contact pad and the contact plug facing each other. Accordingly, metal silicide formed between contact surfaces of the contact pad and the contact plug may be prevented from being damaged by permeation of a cleaning solution while forming an adjacent contact plug. Thus, the contact pad may be prevented from being damaged during a subsequent process of forming a contact plug to be connected to a capacitor, to thereby prevent an electrical short between adjacent contact plugs.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

1. A wiring structure, comprising:
a contact pad electrically connected to a contact region of a substrate;
a contact plug provided on the contact pad and electrically connected to the contact pad;
a spacer facing an upper side surface of the contact pad and sidewalls of the contact plug;
an insulation interlayer pattern having an opening, the contact plug and the spacer being provided in the opening.

2. The wiring structure of claim 1, wherein a lower portion of the opening has a width greater than a width of an upper surface of the contact pad.

3. The wiring structure of claim 1, wherein the contact pad is adjacent to a contact pad for a capacitor, the contact pad for a capacitor being electrically connected to the contact region of the substrate.

4. The wiring structure of claim 1, wherein the spacer surrounds an upper sidewall of the contact pad, and the spacer comprises silicon nitride or silicon oxinitride.

5. The wiring structure of claim 1, further comprising a bit line that is electrically connected to the contact plug.

6-9. (canceled)
